(19) United States
(12) Patent Application Publication
(10) Pub. No.: US 2017/0301620 A1
(43) Pub. Date: Oct. 19, 2017

(54) STRUCTURE AND PROCESS FOR METAL CAP INTEGRATION

(71) Applicant: International Business Machines Corporation, Armonk, NY (US)

(72) Inventors: Chih-chao YANG, Glenmont, NY (US); Daniel Charles EDELSTEIN, White Plains, NY (US)

(21) Appl. No.: 15/130,692

(22) Filed: Apr. 15, 2016

(51) Int. Cl. H01L 23/522; H01L 23/532

(52) U.S. Cl. CPC H01L 23/5226; H01L 23/53238

(57) ABSTRACT

The disclosure relates to semiconductor interconnect structure having enhanced electromigration (EM) reliability in which an oxygen scavenger layer deposited (directly or indirectly) over a surface of conductive material. In one embodiment, the disclosure relates to semiconductor structure having a substrate having a cavity formed therein; a barrier material lining a portion of the cavity; a conductive material formed over the barrier material, the conductive material defining an interconnect layer; a metal cap formed over at least a portion of the conductive material; an oxygen scavenger layer formed over the metal cap layer, the oxygen scavenger layer comprising one or more of Al, TiAl or Al alloys, Mg, TiMg, Mg alloys, and deposited over the metal cap layer using one or more of a Chemical Vapor Deposition (CVD), Atomic Layer Deposition (ALD), Electroless Plating Deposition (ELD) electrodeless deposition techniques; wherein the oxygen scavenger layer removes oxygen from the interface between the conductive material surface and the metal cap layer.

### BACKGROUND

### Field

The disclosure relates to a method, apparatus and structure for metal cap integration. Specifically, the disclosure relates to a semiconductor interconnect structure having enhanced electromigration (EM) reliability in which an oxygen scavenger layer deposited (directly or indirectly) over a surface of a conductive material. The conductive material may be embedded within a low dielectric constant k dielectric material.

### Description of Related Art

Generally, semiconductor devices include a plurality of circuits which form an integrated circuit (IC) fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring structures. The wiring structure typically includes copper, Cu, since Cu based interconnects provide higher speed signal transmission among large numbers of transistors on a complex semiconductor chip as compared with aluminum, Al, based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “parasitic capacitance” and “crosstalk”) are achieved in today's IC product chips by embedding the metal lines and metal vias (e.g., conductive features) in a dielectric material having a dielectric constant of less than 4.0.

In semiconductor interconnect structures, electromigration (EM) has been identified as one metal failure mechanism. The problem not only needs to be overcome during the process development period in order to qualify the process, but it also persists through the lifetime of the chip. Voids are created inside the metal conductors of an interconnect structure due to metal ion movement caused by the high density of current flow. Although the fast diffusion path in metal interconnects varies depending on the overall integration scheme and materials used for chip fabrication, it has been observed that metal atoms, such as Cu atoms, transported along the metal/post planarized dielectric cap interface play an important role on the EM lifetime projection. The EM initial voids first nucleate at the metal/dielectric cap interface and then grow in the direction of the bottom of the interconnect, which eventually results in a circuit dead opening. There is a need for method and structure to substantially eliminate the foregoing problems.

### SUMMARY

In one embodiment, the disclosure relates to semiconductor structure comprising: a substrate having a cavity formed therein; a barrier material lining a portion of the cavity; a conductive material formed over the harrier material, the conductive material defining an interconnect layer; a metal cap formed over at least a portion of the conductive material; an oxygen scavenger layer formed over the metal cap layer, the oxygen scavenger layer comprising one or more of Al, TiAl or Al-alloys, Mg, TiMg, or Mg alloys, and deposited over the metal cap layer using one or more of a Chemical Vapor Deposition (CVD), Atomic Layer Deposition (ALD), or Electroless Plating Deposition (ELD) electrodeless deposition techniques; wherein the oxygen scavenger layer removes oxygen from the interface between the conductive material surface and the metal cap layer.

### BRIEF DESCRIPTION OF THE DRAWINGS

These and other embodiments of the disclosure will be discussed with reference to the following exemplary and non-limiting illustrations, in which like elements are numbered similarly, and where:

FIG. 1 schematically illustrates conventional caps for semiconductor structures to compare performance of metal caps and dielectric caps;

FIG. 2 schematically illustrates forming cavities in a semiconductor body according to one embodiment of the disclosure;

FIG. 3 schematically illustrates formation of a capping material according to one embodiment of the disclosure;

FIG. 4 schematically illustrates deposition of an oxygen scavenger layer according to one embodiment of the disclosure;

FIG. 5A schematically illustrates an exemplary embodiment where a second ILD layer is deposited; and

FIG. 5B schematically illustrates another exemplary embodiment where a second ILD layer is added over the oxygen scavenging layer.

### DETAILED DESCRIPTION

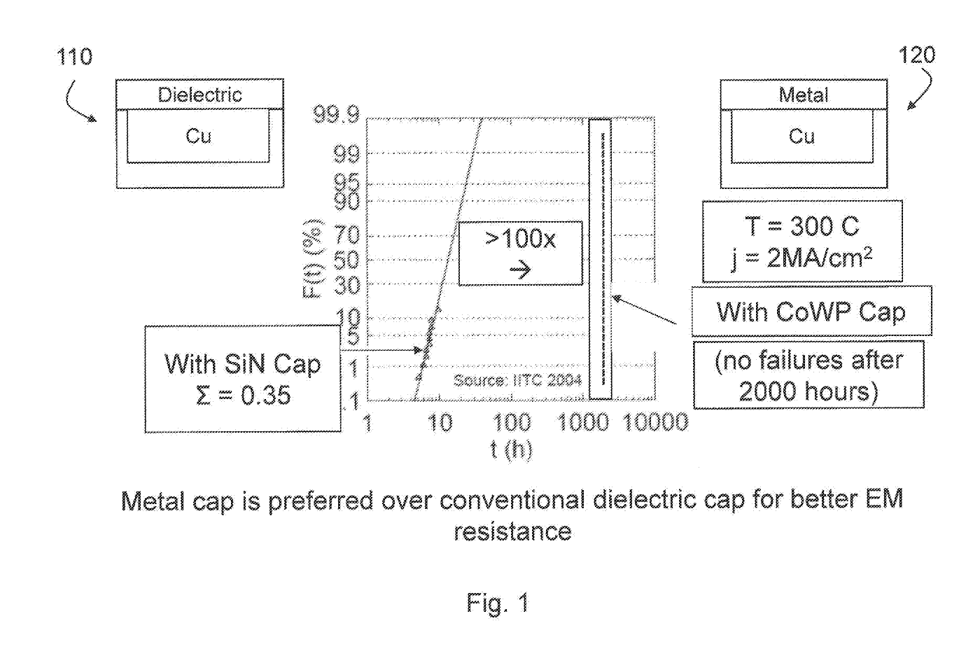

FIG. 1 schematically illustrates conventional caps for semiconductor structures to compare performance of metal caps and dielectric caps. Structure 110 shows a conventional cap formed of a dielectric layer. The structure includes semiconductor body having a cavity formed therein. The cavity is filled with a conductive material such as copper (Cu). While not shown, the structure may include a barrier (interchangeably, a liner) material interposed between the semiconductor body and the conductive material. Structure 120 illustrates a similar structure having a metal capping layer. Finally, FIG. 1 comparatively illustrates the advantage of having a metal capping layer over the dielectric layer for better EM resistance. In addition, the Cu/metal interface provides better adhesion strength than the Cu/dielectric interface, which results in better EM resistance in the Cu/metal capping layer system.

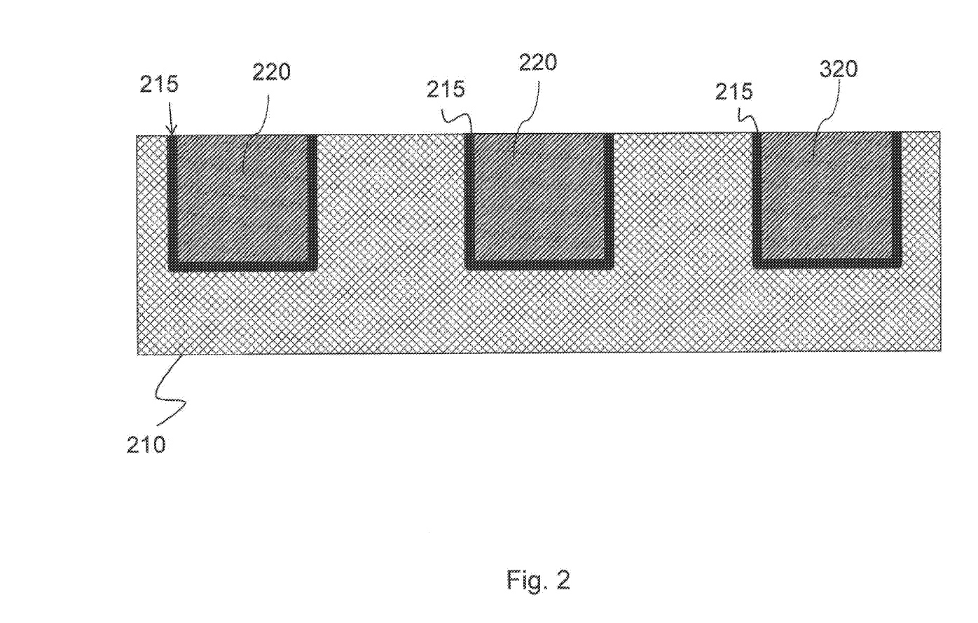

FIG. 2 illustrates semiconductor body 210 having three exemplary cavities formed therein. Each cavity is provided with a barrier layer 215. The barrier layer may cover the cavity in its entirety or a portion thereof. Each cavity is also filled with conductive material 220. The conductive material may define the interconnect layer. The semiconductor body may define an Inter-Layer Dielectric (ILD) material having a low k value. In one embodiment of the disclosure, the interconnect layer 220 may comprise copper (Cu), copper aluminum (CuAl) or an alloy thereof.

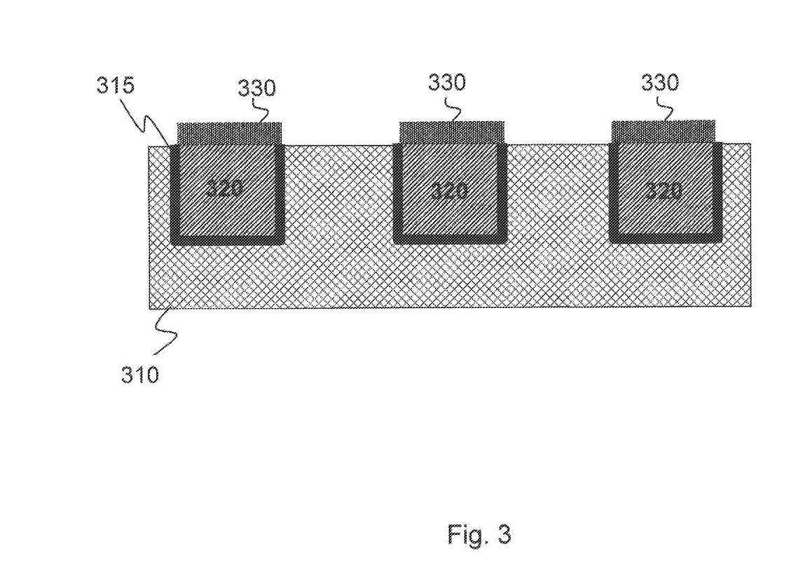

FIG. 3 schematically illustrates deposition of a capping material according to one embodiment of the disclosure. Specifically, FIG. 3 shows semiconductor body (ILD) 310 having three cavities formed therein (as shown in FIG. 2). Each cavity has a barrier layer 315 and an interconnect layer 320. A capping layer 330 is added over the interconnect layer 320. The capping layer 330 may be a metal capping layer. The metal cap may be deposited through chemical vapor deposition (CVD), Atomic Layer Deposition (ALD) Electroless Plating Deposition (ELD) or any other electrodeless deposition technique. The capping layer may comprise Cobalt (Co), Ruthenium (Ru), Manganese (Mn) or an alloy of Co with Tungsten (W), Phosphorus (P) or Boron (B) or any other suitable material. In one embodiment of the disclosure, the metal capping layer is selectively deposited over the interconnect regions to cover all or a portion of each exposed interconnect surface 320.

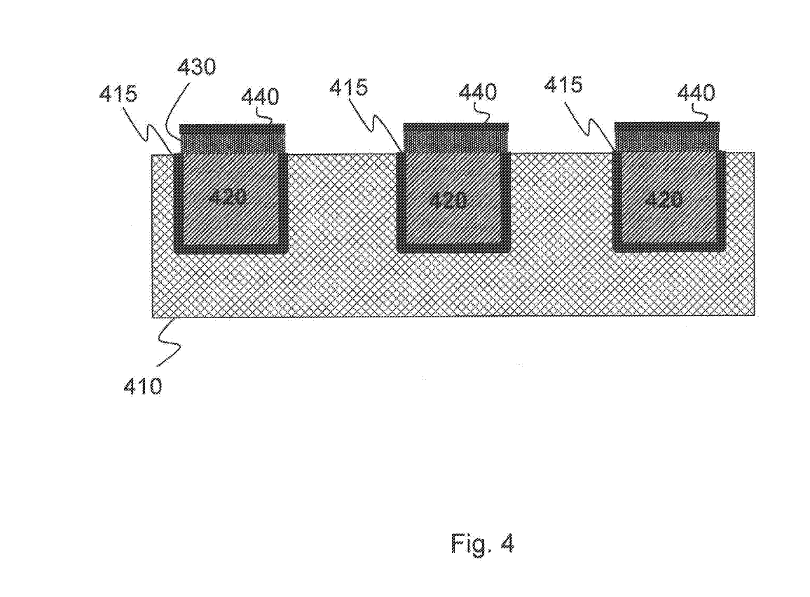

FIG. 4 schematically illustrates deposition of an oxygen scavenger layer according to one embodiment of the disclosure. Here, layer 440 is added atop of layer 430. FIG. 4 also shows ILD layer 410, liners 415, interconnects 420 and capping layers 430. The oxygen scavenger layer 440 may be deposited using CVD, ALD, ELD, or any other electrodeless deposition technique. The oxygen scavenger layer may comprise Al, TiAl or other suitable Al alloys, or Mg, TiMg, or other suitable Mg alloys. In one embodiment of the disclosure, thermal annealing may be done to substantially eliminate or reduce oxygen impurities from the metal cap 430/interconnect 420 interface. In an alternative embodiment, the thermal annealing step may be done later in the process. The oxygen scavenger layer 440 can pull oxygen from the conductive layer (Cu) interface. The oxygen scavenger layer 440 may also prevent oxygen from diffusing into the Cu surface through the capping layer (e.g., Co metal cap). It should be noted that Co is not an oxygen barrier.

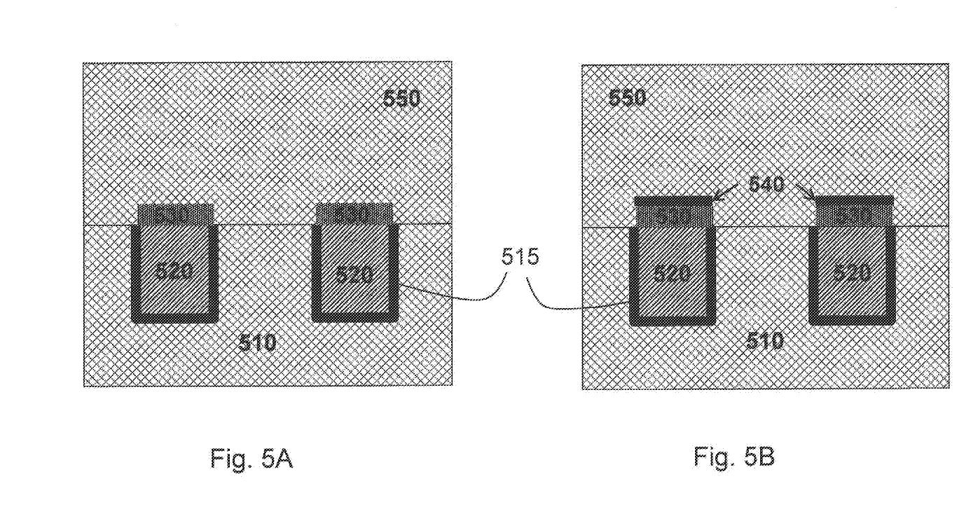

FIG. 5A schematically illustrates an exemplary embodiment where a second ILD layer is deposited. Here the oxygen scavenging layers (see layers 440, FIG. 4) are removed before the second ILD layer 550 is deposited over the structure comprising first ILD layer 510, barrier material layers 515, interconnects 520 and capping layers 530. The second ILD layer may comprise a second dielectric layer. The first and the second dielectric layers may comprise similar or different material.

FIG. 5B schematically illustrates another exemplary embodiment where a second ILD layer is added over the oxygen scavenging layer. Here, the oxygen scavenging layer shown in FIG. 4 is kept intact and a second ILD layer 550 is deposited over the scavenging layers 540. In one embodiment of the disclosure, an insulating cap layer may optionally be deposited before forming the second ILD layer. For example, an insulating cap layer (not shown) may be deposited to cover part or all of the structures 530/540 in FIG. 5B before forming the second ILD layer.

An exemplary process according to one embodiment of the disclosure comprises performing CMP on a first ILD substrate having interconnects formed therein, forming a metal cap over the interconnect, and forming an oxygen scavenger layer over the interconnect layer. In a first example, the surface is then subjected to thermal annealing, wet removal of the oxygen scavenger layer, and insulating cap deposition before the second ILD layer is deposited. In a second example, thermal annealing is followed by insulating the cap layer before the second ILD layer is deposited. In a third example, an insulating cap is formed over the oxygen scavenger layer, followed by thermal annealing before the second ILD layer is deposited. In the first exemplary embodiment, the oxygen scavenger is removed from the final structure. In the second and third exemplary embodiments, the oxygen scavenger is retained in the final structure.

In still another embodiment, thermal annealing may be done at above 400° C. for about 2-60 secs. using a laser annealing system. In yet another embodiment, the annealing temperature may be about 100-400° C. for about 10-180 mins. by using a furnace or a hotplate.

The disclosed embodiments substantially remove loosely-bound oxide molecules from metal, and will improve adhesion between the metal and dielectric layers. The disclosed embodiments also potentially lower the resistivity of the copper lines (interface). The disclosed embodiments also enable thinner metal cap layer to have less impact on Cu resistivity, and possibility reduce insulator Time Dependent Dielectric Breakdown (TDDB) or shorting concerns.

The improved metal/Cu interface enhances reliability. To prevent this interface being contaminated by oxidation, a thicker layer may be deposited according to the disclosed embodiments. Thus, the disclosed embodiments can reduce the metal cap layer thickness.

While the principles of the disclosure have been illustrated in relation to the exemplary embodiments shown herein, the principles of the disclosure are not limited thereto and include any modification, variation or permutation thereof.

1. A semiconductor structure comprising:
a substrate having a cavity formed therein;
a barrier material lining a portion of the cavity;
a conductive material formed directly over the barrier material, the conductive material defining an interconnect layer;
a metal cap formed directly over at least a portion of the conductive material;
an oxygen scavenger layer formed directly over the metal cap layer, the oxygen scavenger layer comprising one or more of Al, TiAl or Al alloys, Mg, TiMg, or Mg alloys, and deposited directly over the metal cap layer using one or more of a Chemical Vapor Deposition (CVD), Atomic Layer Deposition (ALD), or Electroless Plating Deposition (ELD) electrodeless deposition techniques;
wherein the oxygen scavenger layer removes oxygen from the interface between the conductive material surface and the metal cap layer and wherein the oxygen scavenging extends to cover only the metal cap layer.
